(19) United States
(12) Patent Application Publication
(10) Pub. No.: US 2023/0197422 A1
(43) Pub. Date: Jun. 22, 2023

(54) FASTENING ASSEMBLY FOR BEAM BLOCKER IN ION PROCESSING APPARATUS

(71) Applicant: Applied Materials, Inc., Santa Clara, CA (US)

(72) Inventors: Kevin T. Ryan, Wilmington, MA (US); Appu Naveen Thomas, Danvers, MA (US); Adam Calkins, Newmarket, NH (US); Jay R. Wallace, Danvers, MA (US); Tyler Rockwell, Wakefield, MA (US); Solomon Belangedi Basame, Middleton, MA (US); Kevin M. Daniels, Lynnfield, MA (US); Kevin Richard Verrier, Hampton, NH (US)

(73) Assignee: Applied Materials, Inc., Santa Clara, CA (US)

(21) Appl. No.: 17/556,390

(22) Filed: Dec. 20, 2021

(51) Int. Cl. H01J 37/32

(52) U.S. Cl. CPC H01J 37/32807; H01J 37/32422; H01J 37/32623

(57) ABSTRACT

A fastening assembly for fastening a beam blocker to an extraction plate, the fastening assembly including a mounting pin having a shaft portion, a base portion at a first end of the shaft portion, and a head portion at a second end of the shaft portion, a centering sleeve radially surrounding the shaft portion and axially abutting the base portion, the centering sleeve being radially compressible between the shaft portion and the extraction plate and between the shaft portion and the beam blocker, an annular spacer surrounding the centering sleeve and axially abutting the beam blocker, with the centering sleeve extending partially into the spacer, and a latching cap surrounding the shaft portion and axially abutting the spacer, with the shaft portion extending through a through hole of the latching cap, the through hole being smaller than the head portion in a direction perpendicular to an axis of mounting pin.

### FIELD OF THE DISCLOSURE

The disclosure relates generally to processing apparatus for semiconductor devices, and more particularly to a fastening assembly for mounting a beam blocker in an ion processing system.

### BACKGROUND OF THE DISCLOSURE

Plasmas are sometimes used to process semiconductor substrates, such as those used in electronic devices, for applications such as substrate etching, layer deposition, ion implantation, and other processes. Some processing apparatus employ a plasma chamber for generating a plasma to act as an ion source for substrate processing. An ion beam may be extracted through an extraction assembly and directed to a substrate in an adjacent chamber. In some cases, the ion beam may be split around a so-called “beam blocker” disposed adjacent an extraction aperture of the extraction assembly to form a pair of symmetrical, angled ion beamlets directed toward the substrate. The beam blocker may be fastened to an extraction plate on opposing sides of the extraction aperture by a pair of fastening assemblies formed of cooperating mounting pins, spacers, and latches.

A shortcoming associated with fasteners of the type descried above is a tendency to cause misalignment of the beam blocker relative to the extraction aperture, resulting in a lack of symmetry between the beamlets directed toward a target substrate. For example, the entire beam blocker may sag, resulting in a gap above the beam blocker being larger than a gap below the beam blocker. In another example, one side of the beam blocker may sag relative to the opposing side of the beam blocker, resulting in the extraction of “twisted” ion beamlets. Such misalignment may result from variations in the sizes of the components of the fastening assemblies due to manufacturing tolerances, and/or may result from sagging of the beam blocker due to gravity.

With respect to these and other considerations the present disclosure is provided.

### BRIEF SUMMARY

This Summary is provided to introduce a selection of concepts in a simplified form. This Summary is not intended to identify key features or essential features of the claimed subject matter, nor is this Summary intended as an aid in determining the scope of the claimed subject matter.

An embodiment of a fastening assembly for fastening a beam blocker to an extraction plate of an ion processing system in accordance with the present disclosure may include a mounting pin having a cylindrical shaft portion, a base portion at a first end of the shaft portion, and a head portion at an opposing, second end of the shaft portion, a tubular centering sleeve radially surrounding the shaft portion and axially abutting the base portion, the centering sleeve being adapted to be radially compressed between the shaft portion and the extraction plate and between the shaft portion and the beam blocker, an annular spacer radially surrounding the centering sleeve and the shaft portion of the mounting pin and axially abutting the beam blocker, with the centering sleeve extending partially into, and not entirely through, the spacer, and a latching cap radially surrounding the shaft portion and axially abutting the spacer, with the shaft portion extending through a through hole of the latching cap, the through hole of the latching cap being smaller than the head portion in a direction perpendicular to an axis of mounting pin.

An ion processing system in accordance with the present disclosure may include a plasma chamber, a process chamber adjacent the plasma chamber, and an extraction assembly disposed between the plasma chamber and the process chamber. The extraction assembly may include an extraction plate disposed along a side of the plasma chamber and defining an extraction aperture, and a beam blocker disposed adjacent the extraction aperture and fastened to the extraction plate by a fastening assembly. The fastening assembly may include a mounting pin having a cylindrical shaft portion extending through a mounting aperture in the extraction plate and through a mounting aperture in the beam blocker, a base portion at a first end of the shaft portion, and a head portion at an opposing, second end of the shaft portion, a tubular centering sleeve radially surrounding the shaft portion within the mounting aperture of the extraction plate and within the mounting aperture of the beam blocker and axially abutting the base portion, the centering sleeve held in radial compression between the shaft portion and the extraction plate and between the shaft portion and the beam blocker, an annular spacer radially surrounding the centering sleeve and the shaft portion of the mounting pin and axially abutting the beam blocker, the centering sleeve extending partially into, and not entirely through, the spacer, and a latching cap radially surrounding the shaft portion and axially abutting the spacer, with the shaft portion extending through a through hole of the latching cap, the through hole of the latching cap being smaller than the head portion in a direction perpendicular to an axis of mounting pin.

A method of fastening a beam blocker to an extraction plate of an ion processing system in accordance with the present disclosure may include inserting a mounting pin into a mounting aperture in an extraction plate through a front of the extraction plate, the mounting pin having a cylindrical shaft portion, a base portion at a first end of the shaft portion, and a head portion at an opposing, second end of the shaft portion, inserting a first radial half of a centering sleeve into the mounting aperture of the extraction plate, radially intermediate the shaft portion of the mounting pin and the extraction plate and in axial abutment with the base portion of the mounting pin, inserting a second radial half of the centering sleeve into the mounting aperture of the extraction plate, radially intermediate the shaft portion of the mounting pin and the extraction plate and in axial abutment with the base portion of the mounting pin, the second radial half of the centering sleeve mating with the first radial half of the centering sleeve to define a tubular body held in radial compression between the shaft portion of the mounting pin and the extraction plate, placing the beam blocker over the mounting pin and the centering sleeve, with the shaft portion of the mounting pin and the centering sleeve extending through a mounting aperture of the beam blocker, and with the beam blocker being disposed in flat abutment with a rear of the extraction plate, wherein the tubular body of the centering sleeve is held in radial compression between the shaft portion of the mounting pin and the beam blocker, mating first and second radial halves of a spacer together on the centering sleeve to define an annular body axially abutting the beam blocker, with the centering sleeve extending partially into, a through hole of the spacer, placing an annular latching cap over the head portion of the mounting pin, with the head portion being aligned with, and inserted through, a correspondingly shaped through hole of the latching cap, wherein the latching cap is disposed on the shaft portion of the mounting pin and on the spacer in a radially surrounding relationship therewith, and rotating the latching cap relative to the mounting pin to move the through hole of the latching cap out of alignment with the head portion of the mounting pin, thus preventing the latching cap from being axially slid off the mounting pin.

### BRIEF DESCRIPTION OF THE DRAWINGS

FIG. 1 is a vertical cross-sectional view illustrating an ion processing system consistent with embodiments of the present disclosure;

FIG. 2 is a rear perspective view illustrating an extraction assembly of the ion processing system shown in FIG. 1;

FIG. 3 is an exploded rear perspective view illustrating the extraction assembly of the ion processing system shown in FIG. 1;

FIG. 4 is a cross sectional view illustrating a fastening assembly of the extraction assembly shown in FIGS. 2 and 3;

FIG. 5 is a perspective view illustrating a mounting pin and centering sleeve of the fastening assembly shown in FIG. 4;

FIG. 6 is a rear perspective view illustrating the fastening assembly shown in FIG. 4;

FIG. 7 is a flow diagram illustrating an exemplary method of using the fastening assembly of the present disclosure to fasten a beam blocker to an extraction plate of an ion processing system.

### DETAILED DESCRIPTION

The present embodiments will now be described more fully hereinafter with reference to the accompanying drawings, where some embodiments are shown. The subject matter of the present disclosure may be embodied in many different forms and should not be construed as limited to the embodiments set forth herein. These embodiments are provided so this disclosure will be thorough and complete, and will fully convey the scope of the subject matter to those skilled in the art. In the drawings, like numbers refer to like elements throughout.

As used herein, an element or operation recited in the singular and proceeded with the word “a” or “an” are understood as potentially including plural elements or operations as well. Furthermore, references to “an embodiment” of the present disclosure are not intended to be interpreted as precluding the existence of additional embodiments also incorporating the recited features.

The embodiments described herein provide devices and methods for mounting and centering a beam blocker of an ion processing system in a manner that mitigates misalignment of the beam blocker, such as may otherwise result from tolerance stack up in the components of the beam blocker and/or from sagging of the beam blocker due to gravity. Improving the alignment of the beam blocker may enhance the symmetry of ion beamlets projected around the beam blocker, in-turn enhancing the processing (e.g., etching, implantation, etc.) of a target substrate.

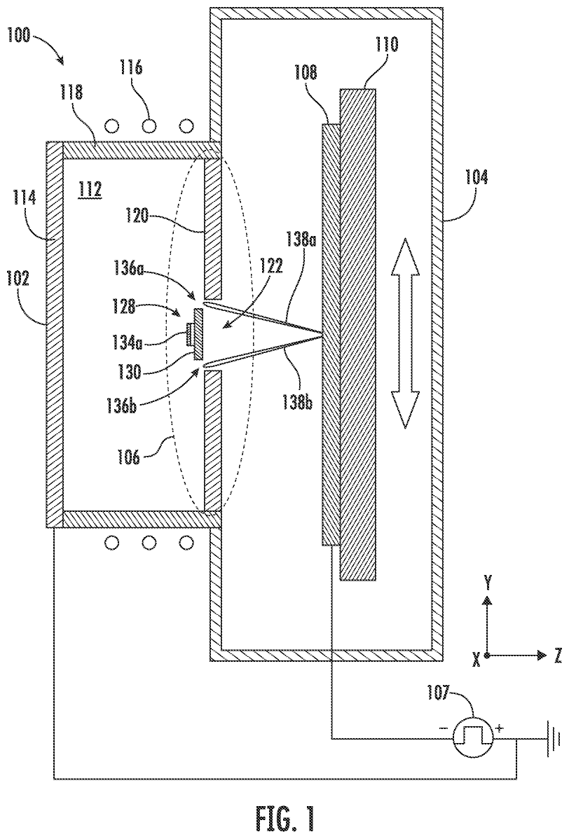

Referring to FIG. 1, there is shown a schematic cross-sectional view illustrating an ion processing system (hereinafter “the system 100”) consistent with embodiments of the present disclosure. The system 100 may include a plasma chamber 102, a process chamber 104, and an extraction assembly 106, described in more detail below. The processing system 100 may further include a voltage supply 107 electrically coupled to generate a bias voltage between the plasma chamber 102 and a substrate 108 (or a platen 110 supporting the substrate 108) being processed. As such, the processing system 100 acts as an ion beam processing system to generate ion beams for processing the substrate 108, arranged proximate to the extraction assembly 106. The plasma chamber 102 may act as a plasma source to generate a plasma 112 by any suitable approach. For example, the plasma chamber 102 may be referenced to a ground potential through an electrically conductive rear wall 114. Ionic (ion) species of interest may be produced in the plasma 112 by inductively coupling rf power generated by a rf power source (not separately shown) from a rf antenna 116 to a working gas within the plasma chamber 102 through a dielectric window 118. Other known means of generating a plasma are possible.

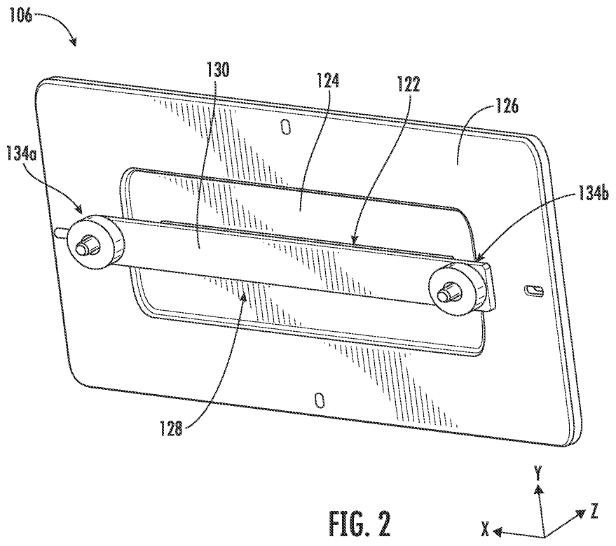

The extraction assembly 106 may further include an extraction plate 120, disposed along a side of the plasma chamber 102. The extraction plate 120 may define an extraction aperture 122 elongated along the X-axis of the Cartesian coordinate system shown in FIG. 1 (note the X-axis extends perpendicularly into the plane of the page). The extraction aperture 122 may allow ions from the plasma chamber 102 to pass through to the substrate 108 as further described below. Referring to FIG. 2, a rear perspective view illustrating the extraction assembly 106 in isolation is shown. As best shown in this view, the extraction aperture 122 may be formed in a recessed portion 124 of an interior surface 126 of the extraction plate 120 (i.e., the surface of the extraction plate 120 facing the interior of the plasma chamber 102 shown in FIG. 1). The extraction assembly 106 may further include a beam blocker assembly 128 disposed adjacent the extraction aperture 122 (see also FIG. 1). The beam blocker assembly 128 may include a beam blocker 130 elongated along the X-axis of the Cartesian coordinate system shown and having a height measured along the Y-axis of the Cartesian coordinate system equal to, or nearly equal to, a height of the extraction aperture 122. The beam blocker 130 may be fastened to the interior surface 126 of the extraction plate 120 on opposing longitudinal sides of the recessed portion 124 by first and second fastening assemblies 134a, 134b (described in greater detail below).

Referring back to FIG. 1, when a negative voltage is applied to the substrate 108 (or to the platen 110) with respect to the plasma chamber 102 in the presence of the plasma 112, plasma menisci are formed in slits (sub-apertures) 136a, 136b between the beam blocker 130 and the extraction plate 120 (i.e., above and below the beam blocker 130). The beam blocker 130 may be vertically centered (i.e., centered along the Y-axis of the Cartesian coordinate system) relative to the extraction aperture 122 to facilitate the formation and extraction of two symmetrical, angled ion beamlets 138a, 138b directed toward the substrate 108. Ion beam processing of the substrate 108 takes place by scanning the substrate 108 in the along the Y-axis of the Cartesian coordinate system, and may also include rotating the substrate around the Z-axis of the Cartesian coordinate system.

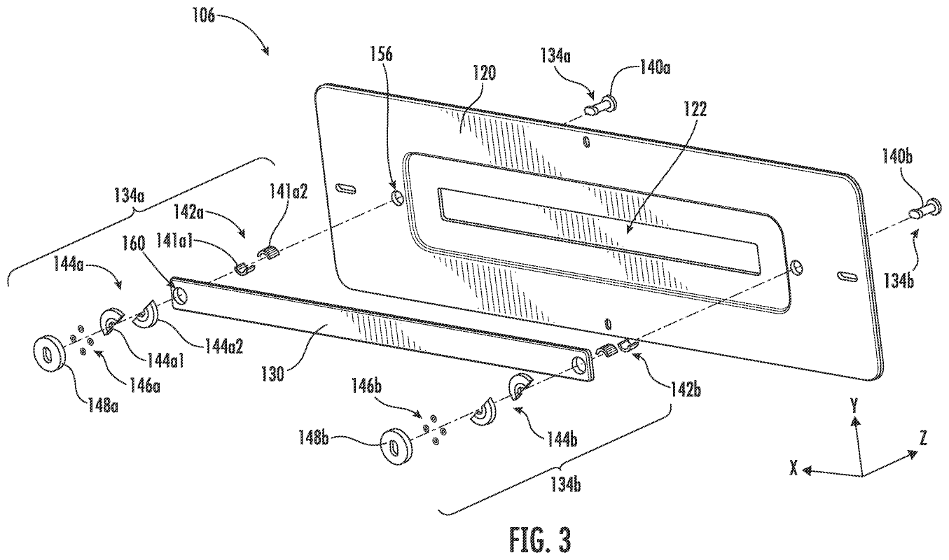

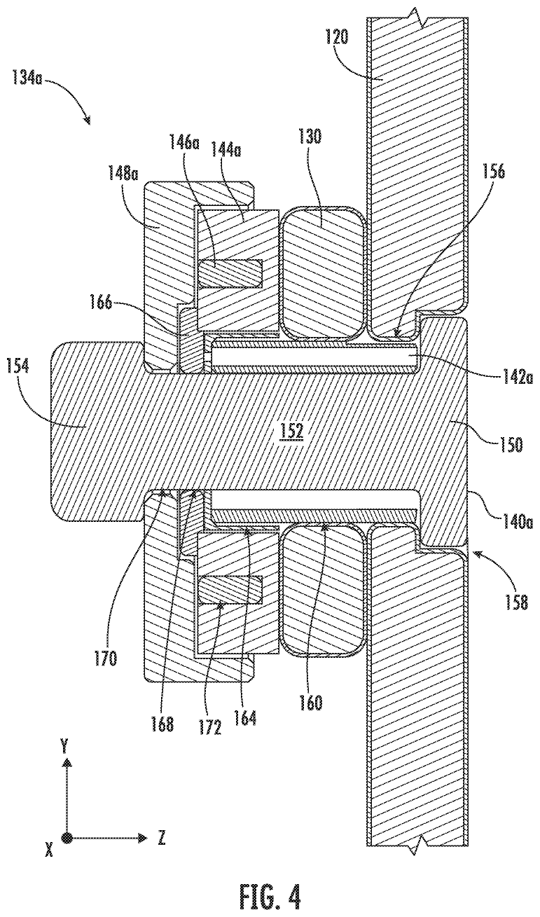

Referring to FIGS. 3 and 4, an exploded rear perspective view illustrating the extraction assembly 106 and a detailed cross-sectional view illustrating the extraction plate 120 and the first fastening assembly 134ba are shown, respectively. The following description will refer to these figures in tandem. The first and second fastening assemblies 134a, 134b are generally identical, and thus the depiction of the first fastening assembly 134ba provided in FIG. 4, and the appurtenant description provided below, shall be understood to also be representative of the second fastening assembly 134b.

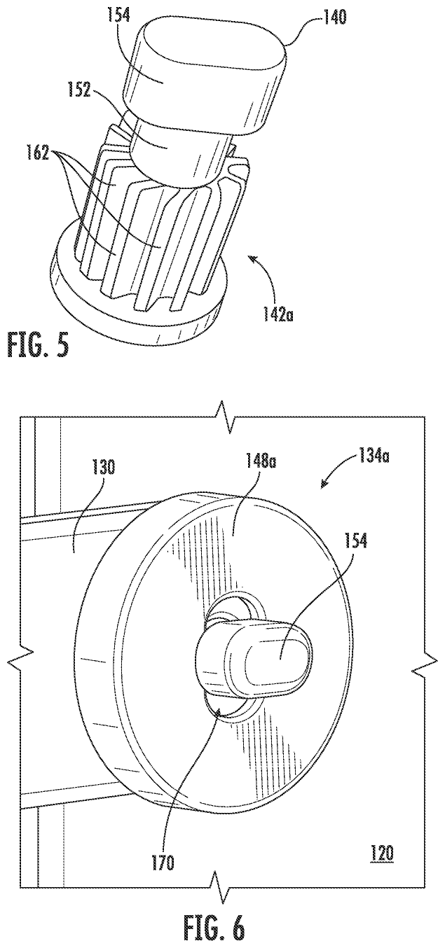

As briefly described above, the first and second fastening assemblies 134a, 134b are adapted to fasten the beam blocker 130 to the extraction plate 120 in a manner that ensures or improves vertical centering and alignment of the beam blocker 130 with respect to the extraction aperture 122. The first and second fastening assemblies 134a, 134b may include respective mounting pins 140a, 140b, centering sleeves 142a, 142b, spacers 144a, 144b, O-rings 146a, 146b, and latching caps 148a, 148b. Referring to FIG. 4, the mounting pin 140a may include a cylindrical base portion 150, a cylindrical shaft portion 152 extending from the base portion 150 and having a smaller diameter than the base portion 150, and an oblong head portion 154 (see FIGS. 5 and 6 for views of the oblong shape of the head portion 154) having a height measured along the Y-axis of the Cartesian coordinate system greater than the diameter of the shaft portion 152. In various alternative embodiments, the base portion 152 may have shapes other than cylindrical, where such shapes are larger along the Y-axis and/or X-axis of the Cartesian coordinate system than the shaft portion 152. Likewise, in various alternative embodiments, the head portion 154 may have shapes other than oblong, where such shapes are larger along the Y-axis and/or X-axis of the Cartesian coordinate system than the shaft portion 152.

The mounting pin 140a may extend through a mounting aperture 156 in the extraction plate 120, with the base portion 150 of the mounting pin 140a disposed within a counterbore 158 of the mounting aperture 156 formed in a front surface (i.e., rightmost surface as oriented in FIG. 4) of the extraction plate 120 in a close clearance relationship therewith. The mounting aperture 156 may have a diameter larger than the diameter of the shaft portion 152. In various non-limiting examples, the diameter of the mounting aperture 156 may be 12.34 millimeters+/−.08 millimeters larger than the diameter of the shaft portion 152. The forward-facing surface of the base portion 150 may be generally coplanar with the front surface of the extraction plate 120.

The shaft portion 152 of the mounting pin 140a may extend through a mounting aperture 160 in the beam blocker 130. The diameter of the mounting aperture 160 may be equal to, or similar to, the diameter of the mounting aperture 156 in the extraction plate 120. In various non-limiting examples, diameter of the mounting aperture 160 may be 12.14 millimeters+/−.08 millimeters. The centering sleeve 142a may be a generally tubular member formed of a resilient material. The centering sleeve 142a may surround the shaft portion 152 of the mounting pin 140a and may extend through the mounting apertures 156, 160 of the extraction plate 120 and the beam blocker 130 with a forwardmost end of the centering sleeve 142a abutting the base portion 150 of the mounting pin 140a. The centering sleeve 142a may have an uncompressed outer diameter slightly larger than the diameters of the mounting apertures 156, 160 of the of the extraction plate 120 and the beam blocker 130. In various non-limiting examples, the uncompressed outer diameter of the centering sleeve 142a may be 12.83 millimeters+/−.05 millimeters larger than the diameters of the mounting apertures 156, 160 of the extraction plate 120 and the beam blocker 130. When the centering sleeve 142a is operatively installed in the first fastening assembly 134a as shown in FIG. 4, the centering sleeve 142a may be held in radial compression between the shaft portion 152 of the mounting pin 140a and the beam blocker 130 and extraction plate 120 (e.g., via interference fit/friction fit). Thus, regardless of variations or discrepancies in the diameter of the mounting pin 140a or the diameters of the mounting apertures 156, 160 (such as may be the result of manufacturing tolerances), the centering sleeve 142a may prevent or mitigate radial movement or “play” of the beam blocker 130 relative to the mounting pin 140a and extraction plate 120 and may establish and preserve vertical centering/alignment of the beam blocker 130 relative to the extraction aperture 122.

In various embodiments, the centering sleeve 142a may be formed of polytetrafluoroethylene (PTFE) or other similarly resilient, plasma resistant material. The present disclosure is not limited in this regard. Referring to FIG. 5, the centering sleeve 142a may include a plurality of axially elongated, radially extending fins 162. The fins 162 may be flexible and may facilitate or enhance the radial resilience and/or elasticity of the centering sleeve 142a. Since the centering sleeve 142a may have an inner diameter smaller than the head portion 154 of the mounting pin 140a, and since the centering sleeve 142a thus cannot be slid axially onto the shaft portion 152 of the mounting pin 140a, the centering sleeve 142a may be formed of separate, first and second radial halves 142a1, 142a2 (see FIG. 3) mated together on the shaft portion 152 to define the tubular centering sleeve 142a.

Referring again to FIGS. 3 and 4, the spacer 144a of the first fastening assembly 134a may be an annular, washer-like member disposed on (i.e., radially surrounding) the centering sleeve 142a and abutting the beam blocker 130. In various embodiments, the centering sleeve 142a may extend partially into, and not entirely through, the spacer 144a as shown in FIG. 4. The present disclosure is not limited in this regard. The spacer 144a may define a through hole 164 having a diameter larger than the outer diameter of the centering sleeve 142a (there is no requirement for snug, radial engagement between the spacer 144a and the centering sleeve 142a). In various non-limiting embodiments, the spacer 144a may include a radially inwardly extending flange 166 radially overhanging a rear side of the through hole 164. The flange 166 may define a secondary through hole 168 having a smaller diameter than the through hole 164 and may serve to shield the centering sleeve 142a from ionic bombardment during operation of the system 100 (see FIG. 1) to prevent or mitigate etching of the centering sleeve 142a. Alternative embodiments of the present disclosure are contemplated wherein the flange 166 may be omitted. The spacer 144a may be formed of a plasma resistant, dielectric material, such as ceramic alumina. The present disclosure is not limited in this regard. Like the centering sleeve 142a, the spacer 144a may be formed of separate, first and second radial halves 144a1, 144a2 (see FIG. 3) mated together on the shaft portion 152 and centering sleeve 142a to define the annular spacer 144a.

The latching cap 148a of the first fastening assembly 134a may be a generally annular, cap-shaped member disposed on (i.e., radially surrounding) the shaft portion 152 of the mounting pin 140a and the spacer 144a, and axially abutting the rear of the spacer 144a. The latching cap 148a may define a through hole 170 having an oblong shape similar to, though slightly larger than, the shape of the head portion 154 of the mounting pin 140a (best shown in FIG. 6). Thus, during installation of the latching cap 148a, the through hole 170 may be aligned with the head portion 154, and the latching cap 148a may be slid axially onto the mounting pin 140, into axial engagement with the spacer 144a, with the head portion 154 passing through the through hole 170. The O-rings 146a of the first fastening assembly 134a may be formed of a resilient material and may be disposed within respective, circumferentially spaced cavities 172 in the rear surface of the spacer 144a. When the O-rings 146a are in an uncompressed state, they may protrude slightly from the cavities 172. When the latching cap 148a is brought into axial engagement with the rear surface of the spacer 144a, the O-rings 146a may be compressed. While the latching cap 148a is held in this position, with the O-rings 146a held under compression, the latching cap 148a may be rotated 90 degrees (or within a range surrounding 90 degrees, e.g., 60 degrees-120 degrees) about its axis, thus rotating the through hole 170 out of alignment with the head portion 154 of the mounting pin 140a (as shown in FIG. 6). With the latching cap 148a installed thusly, the head portion 154 may prevent the spacer 144a from moving rearwardly along the X-axis of the Cartesian coordinate system, and the spring force of the compressed O-rings 146a may exert axially directed forces on the latching cap 148a and the spacer 144a to hold the head portion 154, the latching cap 148a, the spacer 144a, the beam blocker 130, and the extraction plate 120 in firm axial engagement with one another.

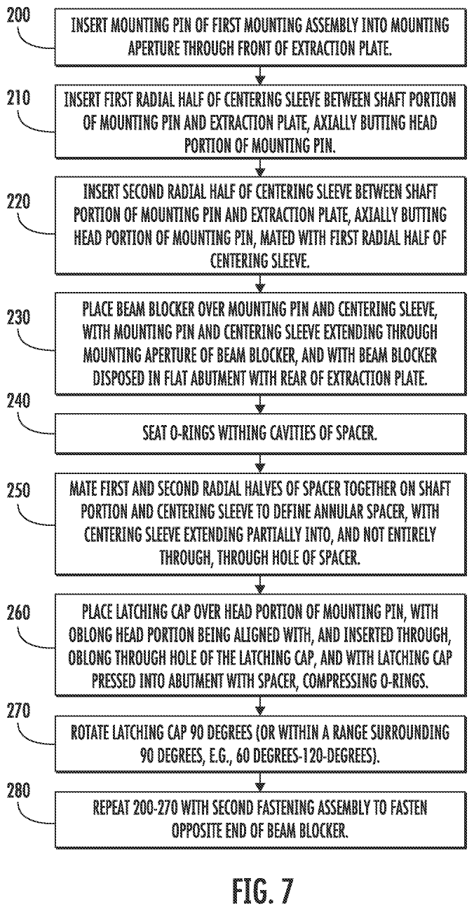

Referring to FIG. 7, a flow diagram illustrating an exemplary method of installing the beam blocker 130 of the extraction assembly 106 using the above-described first and second fastening assemblies 134a, 134b is shown. Installation of the first fastening assembly 134a will be described in detail and, since the first and second fastening assemblies 134a, 134b are generally identical, the following description shall be understood to also be representative of the method of installing the second fastening assembly 134b. The method will now be described in conjunction with the illustrations of the extraction assembly 106 and the first and second fastening assemblies 134a, 134b shown in FIGS. 1-6.

At block 200 of the exemplary method, the mounting pin 140a may be inserted into the mounting aperture 156 through front of the extraction plate 120 and the base portion 150 of the mounting pin 140a may be seated within the counterbore 158 of the mounting aperture 156. Seated thusly, the forward-facing surface of the base portion 150 may be generally coplanar with the front surface of the extraction plate 120.

At block 210 of the exemplary method, the first radial half 142a1 of the centering sleeve 142a may be inserted into mounting aperture 156 through the rear of the extraction plate 120 and may be seated within the mounting aperture 156 radially intermediate the shaft portion 152 of the mounting pin 140a and the extraction plate 120 and in axial abutment with the base portion 150 of the mounting pin 140a. At block 220 of the method, the second radial half 142a1 of the centering sleeve 142a may be inserted into mounting aperture 156 through the rear of the extraction plate 120 and may be seated within the mounting aperture 156 radially intermediate the shaft portion 152 of the mounting pin 140a and the extraction plate 120 and in axial abutment with the base portion 150 of the mounting pin 140a. The first and second radial halves 142a1, 142a2 may be mated together on the shaft portion 152 to define the tubular centering sleeve 142a. Seated within the mounting aperture 156 thusly, the centering sleeve 142a may be held in radial compression between the shaft portion 152 of the mounting pin 140a and the extraction plate 120 (e.g., via interference fit/friction fit).

At block 230 of the exemplary method, the beam blocker 130 may be placed over the mounting pin 140a and the centering sleeve 142a, with the shaft portion 152 of the mounting pin 140a and the centering sleeve 142a extending through the mounting aperture 160 of the beam blocker 130, and with the beam blocker 130 being disposed in flat abutment with the rear of the extraction plate 120. Seated within the mounting aperture 160 thusly, the centering sleeve 142a may be held in radial compression between the shaft portion 152 of the mounting pin 140a and the beam blocker 130 (e.g., via interference fit/friction fit).

At block 240 of the exemplary method, the O-rings 146a may be seated within respective cavities 172 in the first and second radial halves 144a1, 144a2 of the spacer 144a. When the O-rings 146a are in an uncompressed state, they may protrude slightly from the cavities 172. At block 250 of the method, the first and second radial halves 144a1, 144a2 may be mated together on the shaft portion 152 and centering sleeve 142a to define the annular spacer 144a axially abutting a rear of the beam blocker 130, with the centering sleeve 142a extending partially into, and not entirely through, the through hole 164 of the spacer 144a. In various non-limiting embodiments, the spacer 144a may include a radially inwardly extending flange 166 radially overhanging a rear side of the through hole 164. The flange 166 may define a secondary through hole 168 having a smaller diameter than the through hole 164 and may serve to shield the centering sleeve 142a from ionic bombardment during operation of the system 100 to prevent or mitigate etching of the centering sleeve 142a.

At block 260 of the exemplary method, the latching cap 148a may be placed over the head portion 154 of the mounting pin 140a, with the oblong head portion 154 being aligned with, and inserted through, the correspondingly oblong through hole 170 of the latching cap 148a. The latching cap may be disposed on the shaft portion 152 of the mounting pin 140a and on the spacer 144a in a radially surrounding relationship therewith. The latching cap 148a may be pressed into axial abutment with the rear of the spacer 144a, with the O-rings 146a being compressed into their respective cavities 172. While the latching cap 148a is held in this position, with the O-rings 146a held under compression, the latching cap 148a may, at block 270 of the exemplary method, be rotated 90 degrees (or within a range surrounding 90 degrees, e.g., 60 degrees-120 degrees) about its axis, thus rotating the through hole 170 out of alignment with the head portion 154 of the mounting pin 140a. With the latching cap 148a installed thusly, the head portion 154 may prevent the spacer 144a from moving rearwardly, and the spring force of the compressed O-rings 146a may exert axially directed forces on the latching cap 148a and the spacer 144a to hold the head portion 154, the latching cap 148a, the spacer 144a, the beam blocker 130, and the extraction plate 120 in firm axial engagement with one another.

At block 280 of the exemplary method, the actions performed in the above-described blocks 200-270 with respect to the first fastening assembly 134a may be repeated with the second fastening assembly 134b to fasten the opposing longitudinal end of the beam blocker 130 to the extraction plate 120.

In view of the above, the present disclosure provides at least the following advantages. As a first advantage, the fastening assemblies of the present disclosure operate to prevent or mitigate misalignment of a beam blocker relative to an extraction aperture of an ion processing system, thus ensuring or enhancing the symmetry of ion beamlets projected around the beam blocker toward a target substrate. As a second advantage, the fastening assemblies of the present disclosure can be quickly and easily installed. As a third advantage, the fastening assemblies of the present disclosure are self-protective against undesirable ion etching of internal components (i.e., the centering sleeves 142a, 142b).

While certain embodiments of the disclosure have been described herein, the disclosure is not limited thereto, as the disclosure is as broad in scope as the art will allow and the specification may be read likewise. Therefore, the above description is not to be construed as limiting. Those skilled in the art will envision other modifications within the scope and spirit of the claims appended hereto.

1. A fastening assembly for fastening a beam blocker to an extraction plate of an ion processing system, the fastening assembly comprising:
a mounting pin having a cylindrical shaft portion, a base portion at a first end of the shaft portion, and a head portion at an opposing, second end of the shaft portion;
a tubular centering sleeve radially surrounding the shaft portion and axially abutting the base portion, the centering sleeve being adapted to be radially compressed between the shaft portion and the extraction plate and between the shaft portion and the beam blocker;
an annular spacer radially surrounding the centering sleeve and the shaft portion of the mounting pin and axially abutting the beam blocker, with the centering sleeve extending partially into, and not entirely through, the spacer; and
a latching cap radially surrounding the shaft portion and axially abutting the spacer, with the shaft portion extending through a through hole of the latching cap, the through hole of the latching cap being smaller than the head portion in a direction perpendicular to an axis of mounting pin.

2. The fastening assembly of claim 1, further comprising a plurality of O-rings disposed within corresponding cavities formed in the spacer and confronting the latching cap.

3. The fastening assembly of claim 1, wherein the head portion of the mounting pin has an oblong shape.

4. The fastening assembly of claim 1, wherein the shaft portion of the mounting pin extends through a through hole of the spacer, the spacer having a radially inwardly extending flange radially overhanging a rear side of the through hole and covering an end of the centering sleeve to shield the centering sleeve from ionic bombardment.

5. The fastening assembly of claim 1, wherein the centering sleeve is formed of separate, first and second radial halves adapted to be mated together.

6. The fastening assembly of claim 1, wherein the spacer is formed of separate, first and second radial halves adapted to be mated together.

7. The fastening assembly of claim 1, wherein the base portion of the mounting pin is larger than the shaft portion of the mounting pin in a direction perpendicular to the axis of the mounting pin.

8. The fastening assembly of claim 1, wherein the centering sleeve is formed of polytetrafluoroethylene (PTFE).

9. An ion processing system comprising:
a plasma chamber;
a process chamber disposed adjacent the plasma chamber; and
an extraction assembly comprising:
an extraction plate disposed along a side of the plasma chamber and defining an extraction aperture;
a beam blocker disposed adjacent the extraction aperture and fastened to the extraction plate by a fastening assembly, the fastening assembly comprising:
a mounting pin having a cylindrical shaft portion extending through a mounting aperture in the extraction plate and through a mounting aperture in the beam blocker, a base portion at a first end of the shaft portion, and a head portion at an opposing, second end of the shaft portion;
a tubular centering sleeve radially surrounding the shaft portion within the mounting aperture of the extraction plate and within the mounting aperture of the beam blocker and axially abutting the base portion, the centering sleeve held in radial compression between the shaft portion and the extraction plate and between the shaft portion and the beam blocker;
an annular spacer radially surrounding the centering sleeve and the shaft portion of the mounting pin and axially abutting the beam blocker, the centering sleeve extending partially into, and not entirely through, the spacer; and
a latching cap radially surrounding the shaft portion and axially abutting the spacer, with the shaft portion extending through a through hole of the latching cap, the through hole of the latching cap being smaller than the head portion in a direction perpendicular to an axis of mounting pin.

10. The ion processing system of claim 9, further comprising a plurality of O-rings disposed within corresponding cavities formed in the spacer, the O-rings being held in compression between the latching cap and the spacer.

11. The ion processing system of claim 9, wherein the head portion of the mounting pin has an oblong shape.

12. The ion processing system of claim 9, wherein the shaft portion of the mounting pin extends through a through hole of the spacer, the spacer having a radially inwardly extending flange radially overhanging a rear side of the through hole and covering an end of the centering sleeve to shield the centering sleeve from ionic bombardment.

13. The ion processing system of claim 9, wherein the centering sleeve is formed of separate, first and second radial halves mated together on the shaft portion of the mounting pin.

14. The ion processing system of claim 9, wherein the spacer is formed of separate, first and second radial halves adapted to be mated together on the centering sleeve.

15. The ion processing system of claim 9, wherein the base portion of the mounting pin is larger than the shaft portion of the mounting pin in a direction perpendicular to the axis of the mounting pin.

16. A method of fastening a beam blocker to an extraction plate of an ion processing system, the method comprising:
inserting a mounting pin into a mounting aperture in an extraction plate through a front of the extraction plate, the mounting pin having a cylindrical shaft portion, a base portion at a first end of the shaft portion, and a head portion at an opposing, second end of the shaft portion;
inserting a first radial half of a centering sleeve into the mounting aperture of the extraction plate, radially intermediate the shaft portion of the mounting pin and the extraction plate and in axial abutment with the base portion of the mounting pin;
inserting a second radial half of the centering sleeve into the mounting aperture of the extraction plate, radially intermediate the shaft portion of the mounting pin and the extraction plate and in axial abutment with the base portion of the mounting pin, the second radial half of the centering sleeve mating with the first radial half of the centering sleeve to define a tubular body held in radial compression between the shaft portion of the mounting pin and the extraction plate;
placing the beam blocker over the mounting pin and the centering sleeve, with the shaft portion of the mounting pin and the centering sleeve extending through a mounting aperture of the beam blocker, and with the beam blocker being disposed in flat abutment with a rear of the extraction plate, wherein the tubular body of the centering sleeve is held in radial compression between the shaft portion of the mounting pin and the beam blocker;
mating first and second radial halves of a spacer together on the centering sleeve to define an annular body axially abutting the beam blocker, with the centering sleeve extending partially into, a through hole of the spacer;
placing an annular latching cap over the head portion of the mounting pin, with the head portion being aligned with, and inserted through, a correspondingly shaped through hole of the latching cap, wherein the latching cap is disposed on the shaft portion of the mounting pin and on the spacer in a radially surrounding relationship therewith; and
rotating the latching cap relative to the mounting pin to move the through hole of the latching cap out of alignment with the head portion of the mounting pin, thus preventing the latching cap from being axially slid off the mounting pin.

17. The method of claim 16, wherein the spacer has a radially inwardly extending flange radially overhanging a rear side of the through hole and covering an end of the centering sleeve to shield the centering sleeve from ionic bombardment.

18. The method of claim 16, further comprising disposing a plurality of O-rings within corresponding cavities formed in the spacer.

19. The method of claim 18, wherein placing the latching cap over the head portion of the mounting pin comprises compressing the plurality of O-rings within their corresponding cavities.

20. The method of claim 16, wherein inserting the mounting pin into the mounting aperture of the extraction plate comprises disposing the base portion of the mounting pin within a counterbore of the mounting aperture of the extraction plate.
